(19) United States
(12) Patent Application Publication
(10) Pub. No.: US 2023/0347580 A1
(43) Pub. Date: Nov. 2, 2023

(54) DEVICE AND METHOD FOR STEREOLITHOGRAPHIC THREE DIMENSIONAL PRINTING

(71) Applicants: FUNDACIO INSTITUT DE BIOENGINYERIA DE CATALUNYA (IBEC), BARCELONA (ES); JOHANN WOLFGANG GOETHE-UNIVERSITÄT FRANKFURT AM MAIN, FRANKFURT AM MAIN (DE); UNIVERSITAT DE BARCELONA, BARCELONA (ES); MYCRONIC AB, TÄBY (SE)

(72) Inventors: ELENA MARTÍNEZ FRAIZ, BARCELONA (ES); NÚRIA TORRAS ANDRÉS, BARCELONA (ES); FRANCESCO PAMPALONI, FRANKFURT AM MAIN (DE); ERNST H. K. STELZER, MECKESHEIM (DE); GUSTAF MÅRTENSSON, SOLNA (SE); ROBERT EKLUND, ÖSTERSKÄR (SE); NUR ISMAIL, SOLNA (SE)

(21) Appl. No.: 18/006,086

(22) PCT Filed: Aug. 9, 2021
(86) PCT No.: PCT/EP2021/072200

§ 371 Date: Jan. 19, 2023

(30) Foreign Application Priority Data
Aug. 11, 2020 (EP) 20382743.1

(51) Int. Cl. B29C 64/135; B29C 64/282

(52) U.S. Cl. CPC B29C 64/135; B29C 64/282; B33Y 30/00

(57) ABSTRACT

The present invention refers to a device and method for stereolithograpic three dimensional (3D) printing comprising: a) a container adequate for containing a photopolymerizable polymer, b) at least one laser generator emitting a light beam with a wavelength between 360 nm and 1000 nm, c) modulation means for modulating said light beam into at least two light sheets which are matrices of light, and d) means for irradiating said light sheets in the container containing said photopolymerizable polymer; wherein said at least one laser generator is arranged so that said at least two light sheets are crossed inside said container, leading to polymerization of the photopolymerizable polymer at the crossing of said light sheets.

The present disclosure refers to a device for the stereolithographic three dimensional (3D) printing, and a printing method using said device.

Usually, photopolymerization printers use a digital light processing (DLP) technique or a stereolithographic (SLA) technique.

DLP is a well-known technique, in which a light beam is projected onto a photopolymer in liquid state which hardens as it polymerizes, achieving polymerization. Although printing using this technique has both good accuracy and speed, in particular for polymerizing low molecular weight polymers, it has problems for polymerizing polymers of higher molecular weight, in addition of being a relatively expensive technique and with a low resolution.

The SLA technique is based on projecting a laser onto a photopolymer placed in a container so that said photopolymer hardens. In this case, it is possible to obtain a 3D print while moving the laser along the Z axis providing the following position for polymer hardening. This technique allows polymerization of polymers of higher molecular weight, and has a higher accuracy and printing resolution as compared with DLP systems, although it has a low production speed.

Known is as well the photopolymerization of polymers containing living cells, antibodies or proteins which are kept inside the polymer after phoyopolymerization thereof. In these cases, the low printing speed of the SLA technique impide the correct stacking and viability of the embedded cells, further modifying its mechanical, biochemical and structural properties, without managing to resemble to equivalent cells in any tissue.

The present inventors, after extensive studies, have developed a device for stereolithographic 3D printing that overcomes the above-mentioned drawbacks. The device of the present invention allows achieving high resolution prints at high speeds, fully compatible with stereolithographic three dimensional (3D) printing processes. In addition, the device of the present invention meets the need of a bioprinter allowing 3D printing of photopolymers that may comprise living cells, obtaining a cell viability higher than 99% after impression. Moreover, by using the present printing system, cells are not subjected to any kind of stress, which are otherwise frequent in typical 3D printing processes, in which cells and polymer pass through narrow nozzles, generating undesired stresses, particularly shear stress. The device of the present invention allows to obtain cell-containing structures with the same heterogeneous architecture and mechanical, biochemical and structural properties as any cell microenvironment within tissues, without compromising cell viability due to long printing periods. That is, it is possible to obtain fully functional tissue surrogates at this printing speed.

One objective of the present invention is to provide a device for stereolithographic 3D printing that allows polymerization of photopolymerizable polymers at high speed and in a more efficient manner as compared with devices of the prior art.

More in particular, the present invention refers to a device for stereolithograpic three dimensional (3D) printing comprising:
a) a container adequate for containing a photopolymerizable polymer,
b) at least one laser generator emitting a light beam with a wavelength between 360 nm and 1000 nm,
c) modulation means for modulating said light beam into at least two light sheets, which are matrices of light, and
d) means for irradiating said light sheets in the container containing said photopolymerizable polymer;

wherein said at least one laser generator is arranged so that said light sheets are crossed inside said container, leading to polymerization of the photopolymerizable polymer at the crossing of said light sheets.

Preferably, the device of the present invention comprises two laser generators. Alternatively, the device of the present invention comprises one laser generator. When only one laser generator is used in the device of the present invention, the modulation means comprises a splitter in order to obtain two light beams.

Preferably, said at least one laser generator is arranged so that said at least two light sheets are crossed inside said container containing said photopolymerizable polymer forming an angle greater than 45° between them. More preferably, said laser generator is arranged so that said at least two light sheets are crossed inside said container containing said photopolymerizable polymer forming an angle of 90°.

Preferably, the device of the present invention comprises at least one laser generator emitting light beams with a wavelength between 360 nm and 1000 nm, so that the maximum absortion peak of an photoactivator is as close as posible to the the wavelength of the laser generator. Additionally, by generating a light beam close to 1000 nm, it allows the device to use imaging techniques such as the two-photon illumination technique.

Preferably, said at least one laser generator is capable of generating light beams in the visible spectrum. More preferably, with a wavelength between 360 nm and 450 nm, even more preferably between 395 and 415 nm, most preferably of 405 nm. Preferably, the device of the present invention further comprises means for controlling the time of emission of the light beams onto the container.

Preferably, the device comprises modulation means for modulating said light beams into light sheets, which are a plane arrays or matrices of light. More preferably, the device comprises modulation means for modulating said light beams into light sheets which are coplanar between them.

Preferably, the device of the present invention comprises means for rotating the container. More preferably, the angle of rotation is an angle between 0° and 360°. Even more preferably, the angle of rotation is an angle between 0° and 180°. Preferably, the device of the present invention comprises means for linearly moving the container. This rotation or movement of the container allows the device to perform a volumetric bioprinting or tomographic bioprinting based on tomographic back-projections.

More preferably, the device of the present invention comprises means for positioning the container to any spatial coordinate by both translation and rotation of the container.

Preferably, the device of the present invention comprises means for moving the at least one laser generator.

Preferably, the device of the present invention comprises at least two optic modules located downstream of said at least one laser generator, said optic modules comprising a scanning mirror and a scanning lens. More preferably, said scanning mirror is a galvanometric mirror. Even more preferably, said optic modules further comprise a tube lens and an objective lens.

Preferably, the modulation means comprise at least one pattern generation system. More preferably, the pattern generation system is located between the laser generator and the scanning mirror. Even more preferably, the pattern generator system comprises a photomask. Said photomask allows to module the light beam so that it falls upon inside the container of the photopolymerizable polymer. More prefereable, the device comprises at least two pattern generation systems, being each of said pattern generation systems adequated for modulating each light sheet.

Preferably, the device of the present invention comprises an acoustic-optic modulator. More preferably, it comprises an acousto-optic deflector.

Preferably, the device of the present invention comprises an imaging system. More preferably, it comprises an image capturing element and an objective lens. Even more preferably, the image capturing element is a CCD (charge-coupled device) camera. Preferably, the device comprises two of said imaging systems, being each of the imaging systems aligned with said light sheets.

In a further aspect, the present invention refers to a method for stereolithographic three dimensional printing using a device as disclosed above, which comprises the steps of:
a) providing a container adequate for containing a photopolymerizable polymer,
b) generating at least two light beams with a wavelength between 360 nm and 1000 nm by at least one laser generators,
c) modulating said light beams into light sheets (which are plane light arrays),
d) irradiating said light sheets inside said container containing said photopolymerizable polymer, so that said light sheets are crossed inside said container, so that polymerization of the photopolymerizable polymer occurs at the crossing of said light sheets.

Alternatively, said method further comprises an step of e) rotating and/or linearly moving the container containing the photopolymerizable polymer during the irradiating of the light sheets. By rotating and/or moving the container, this method allows performing a volumetric bioprinting or tomographic bioprinting based on tomographic back-projections, in which a 3D polymerized shape is generated by illuminating with tomographic back-projections generated by the modulated laser beams, which depending on the properties of the container and the polymer, results in faster or more efficient method. This is also an alternative approach near “direct writing” to print a 3D shape out of the gel. Preferably, the at least two light beams generated in step b) are at least two light beams in the visible spectrum.

Preferably, the light beams are modulated into light sheets which are coplanar between them.

Preferably, said photopolymerizable polymer comprises a photoactivator. More preferably, said photoactivator is Eosin Y or lithium phenyl-2 4 6-trimethylbenzoylphosphinate (LAP).

Preferably, the photopolymerizable polymer is a hydrophilic polymer. More preferably, the photopolymerizable polymer is a hydrogel. Even more preferably, said hydrogel is selected from a list comprising norbornene or thyol-functionalized polymers, including 4 arms norbornene PEG, gelatin methacrylate (GelMA) or poliethylenglycol diacrylate (PEGDA), and combinations thereof.

Preferably, the photopolymerizable polymer can be chemically modified to provide them with specific biochemical signals, such as covalent bonding of RGDs-type peptides or proteins, to enhance cellular adhesion.

Said polymers should be clear to the light sheet wavelength, in order to allow photoactivator action, and thus its polymerization. In order to monitor in real time the photopolymerization process, said polymer should be previously labelled with a fluourescent probe, such as a specific label for proteins, peptides o some functional groups present in the polymer formulation, compatible with the light sheet wavelength generated by the laser source.

With the device of the present invention it is possible to use both low and high molecular weight polymers, also allowing combination thereof in a same photopolymerization process, leading to a wide range of possible resulting polymers, each of them with different physical characteristics, being the most important stiffness, density of the resulting matrix, and water absorption capacity.

The resulting hydrogels of the present light sheet photopolymerization process should have mechanical properties similar to those known for in vivo soft tissues, being the apparent elastic modulus in a range between 0.1-100 kPa, preferably lower than 50 kPa in case that polymer contains cells, and even more preferably, lower than 15 kPa.

Likewise, preferably in the resulting hydrogel the total polymer concentration (weight/volume) is lower or equal to 15%, in order to assure that the resulting matrix of the polymerization process is suitable for cell growing and developing contained thereof. When said polymer photopolymerization does not contain cells, total concentration of said photopolymer can be up to 30% or higher.

Preferably, said photopolymerizable polymer comprises living cells, said cells being selected from the list comprising mouse dermis cells (fibroblasts, lymphocytes, macrophages, endothelial cells, among other), or human cells such as dermal papilla, hair follicles, or sweat glands cells, and a combination thereof.

Prefereably, said photopolymerizable polymer is a polymer labelled with fluorescent probes.

Hereinafter, the present invention is described with reference to examples, which however are not intended to limit the present invention.

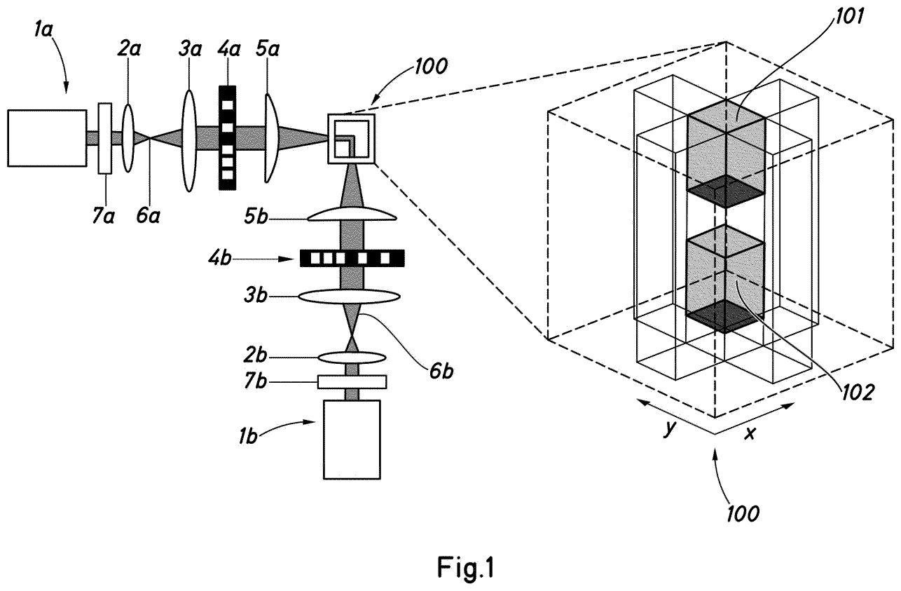

FIG. 1 shows a diagram of a device according to a first embodiment of the present invention.

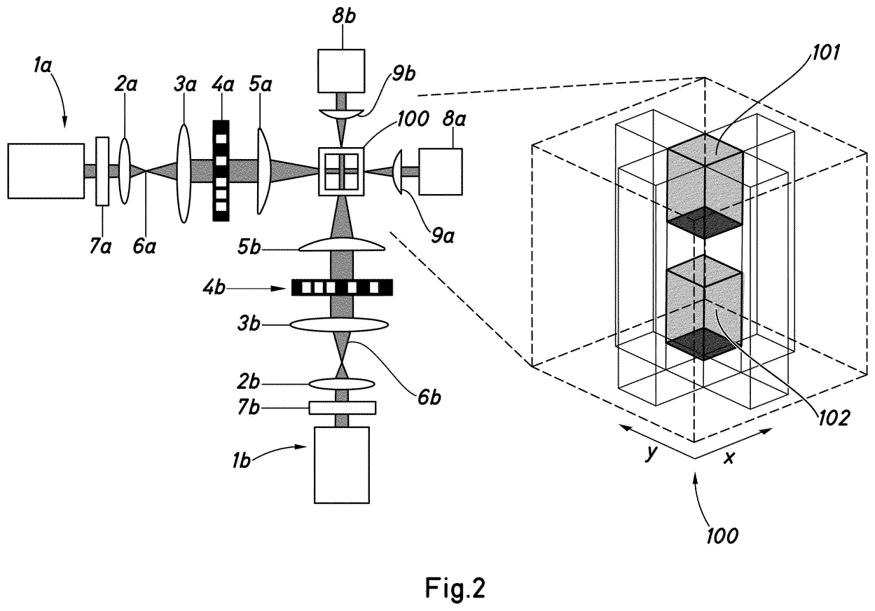

FIG. 2 shows a diagram of a device according to a second embodiment of the present invention.

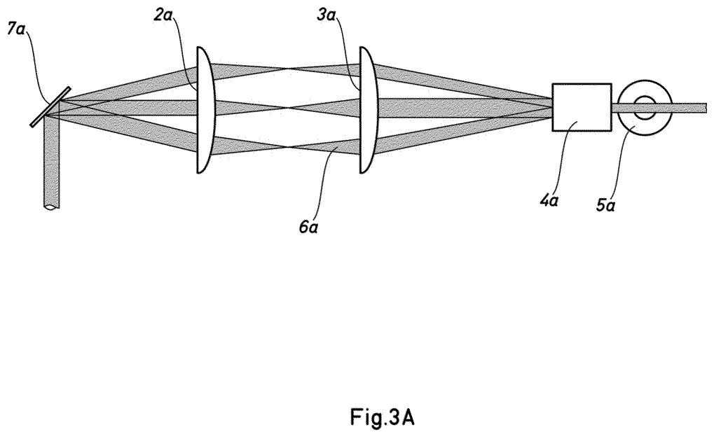

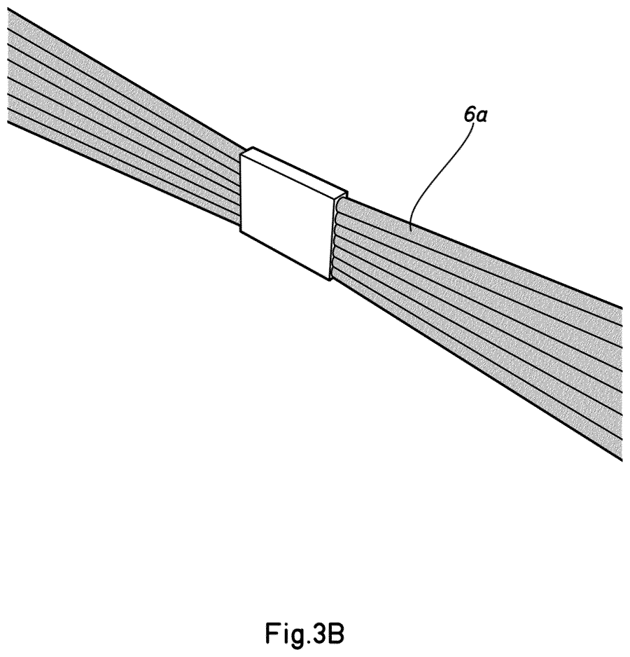

FIGS. 3A and 3B show a schematic example of the optic module and the light modulation used in any of the first and second embodiments of the present invention.

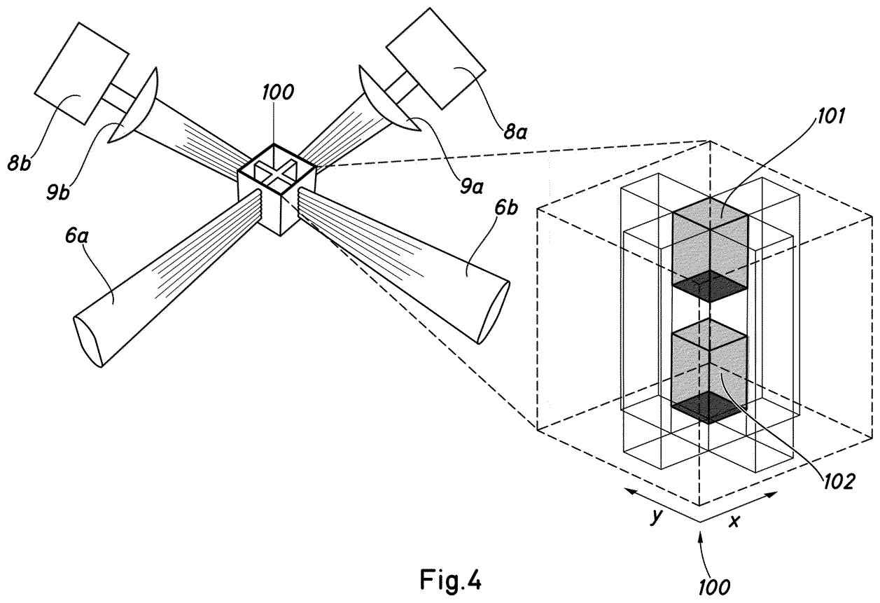

FIG. 4 shows a schematic example of the irradiation of two light beams on a photopolymer according to a third embodiment of the present invention.

FIG. 1 shows a schematic example of a device for stereolithographic three dimensional (3D) printing. The device comprises a container 100 adequate for containing a photopolymerizable polymer and two laser generators 1a, 1b generating respective light beams 6a, 6b. Each generator generates only one light beam, although alternatively said laser generators can be laser generators generating a plurality of light beams. As can be seen in FIG. 1, generators 1a, 1b are provided such that the light beams 6a, 6b are modulated by modulation means into light sheets and are crossed inside the container 100 so that at the cross-point a volume unit or voxel of said photopolymerizable polymer is polymerized. The volume at which the light sheets are crossed is a voxel of said polymer. This combination of two light sheets allows to increase both the illumination energy required for initiating polymerization and its spatial resolution. In this configuration, polymerization occurs in the crossing point of the two light sheets. The device could alternatively comprise only one laser generator and a splitter, thus generating two light beams which are later modulated into two light sheets.

The laser generators 1a, 1b of light beams 6a, 6b of the device of the present invention are arranged such that said light sheets are crossed inside the container 100 containing the photopolymerizable polymer forming an angle higher than 45° between them. More in particular, in FIG. 1 said angle is 90°.

The device of the present invention further comprises modulation means for modulating said light beams 6a, 6b into a light sheet which is a plane array or matrix of light, and means for irradiating said light sheets to the container containing said photopolymerizable polymer.

These light sheets are coplanar, being both of them located in the same XY plane. By being both of them in the same plane and due to their coplanarity, said light sheets are crossed inside the container in a cross-point unit in the XY plane, thus enhancing the printing speed of the device.

Modulation of light beams into light sheets is performed by an optic module. In particular, FIG. 1 shows two optic modules located after the laser generators 1a, 1b. Said optic modules comprise respectively an scanning mirror 7a, 7b and a scanning lens 2a, 2b. More specifically, the light sheet is generated by a pair of galvanometric scanning mirrors 7a, 7b coupled to a scanning lens (as seen in FIG. 2). Said galvanometric scanning mirrors allow having a homogeneous illumination profile which is equivalent to a light sheet which in turn allows applying a constant speed and power on the container 100. The scanning mirrors 7a, 7b perform a translation of the beam 6a, 6b up and down forming a sheet. The device further comprises means for modulating the height of said light sheets. Translation of the light sheet along Z axis allows polymerization of the polymer in a pre-established Z range, without the need of moving the surface where the container is arranged. Without this translation, the polymerization would only be possible in the XY plane where the two light sheets collide if the container or a support where the container is located therein is moved.

The optic module also includes a tube lens 3a, 3b and an illumination objective lens 5a, 5b, preferably of low magnification. With this configuration a desired height of the light sheet is obtained. As a way of an example, this height is of about 4 mm when the objective lens is 5×. This height is defined by the configuration of the lenses. If a higher objective lens would be used, the height (Z) value would be lower. The device further comprises means for modulating the illumination of the light sheet spatially and temporarily, digitally modulating the laser 6a, 6b intensity during the scanning process.

In addition, each of the modulation means comprises a pattern generation system 4a, 4b. Pattern generators 4a, 4b couple the light beam facilitating formation of a light sheet, and are preferably provided after the scanning mirrors 7a, 7b, as shown in the device of FIG. 1. Alternatively, said pattern generator system can be located before the scanning. By using a pattern generation system, the illumination of the container can be performed selectively by previously patterning the polymer, which allows shaping the ilumination in a selective manner.

The pattern generation system is preferably a scanning system based on the acousto-optic deflection and modulation of the exposition beam. One of the advantages consists of allowing an extensive calibration of the beam. This calibration capability allows simplifying the optical design. Preferably, the pattern generation system comprises a photomask. This photomask is a high resolution digital photomask. This photomask enables performing a photopolymerization by using different types of patterns proyected in it, so that the system can project always the same pattern or change the projected pattern en each polymerization layer. The pattern generator may preferably comprise an acousto-optic modulator (AOM). When attached to a pattern generation system, this AOM modulator allows performing a change of the modulation of the pattern at high speed, thus which providing high resolution at high speed. The modulator can be further equipped with control software in order to provide dynamic resolution capabilities.

The device comprises two pattern generation systems 4a, 4b, each of them arranged for modulating each of the two light beams 6a, 6b. Alternatively, the device may comprise only one pattern generator, being adequate for modulating both light beams.

The printing system further comprises objective lenses 5a, 5b. These lenses allow getting images of big samples using microscopy based on light sheets, and are lenses of any known type, being preferably lenses with a high numeric aperture, long working distance, low magnification, and high vision field.

The device depicted in FIG. 1 allows hardening of the polymer that may optionally comprise living cells, antibodies, proteins or any other kind of biological structures, which would thereby create three dimensional (3D) cell-containing structures in a stereolithographic process. In addition, as they are comprised in the hardened photopolymer after being polymerized using the light beams, the cells maintain their position without precipitating down to the bottom of the polymer or the container comprising thereof. Consequently, the device allows a top-down stereolithographic printing, starting with the hardening of the polymer containing cells in the upper part, in addition to the already known ascendening stereolitography performed by other printing devices.

The laser generators 1a, 1b generate laser beams with a wavelength such that its energy is capable to cause the photoactivator activate the initiation of the polymerization reaction of the photopolymerizable polymer. The characteristics of the laser generators and the photoactivator are selected so that the maximum absorption peak of the photoactivator is as close as possible to the wavelength of the source in order to improve the efficiency of the system. Therefore, the wavelength required to initiate the polymerization reaction depends on the absorption spectrum of the photoactivator that will be used. If both the photoactivator and the laser generator source are chosen accordingly, the concentration of the photoactivator required to activate the initiation of the polymerization can be lowered, which in turn would reduce the amount of free radicals generated by the photoactivator. A reduction of the free radicals generated is considered an additional advantage, as highly amounts of them could eventually be harmful for cells. Alternatively, the photoactivator can be selected based on the wavelength of the laser generator.

Therefore, the wavelength required to initiate the polymerization reaction also depends on the absorption spectrum of the photoactivator that will be used. In addition, the required wavelength also depends on the optical configuration and on the presence and characteristics of an acousto-optic modulator and an acousto-optic deflector. In this particular embodiment, said wavelength is between 365 and 1000 nm, more preferable 365 and 450 nm, even more preferable between 395 and 415 nm, most preferably of 405 nm. More specifically, the wavelength required to initiate the polymerization reaction depends on various factors, including the wavelength of the laser generators, and the presence or inexistence of cells. If cells are present, the wavelength of the laser generator should be no lower than 365 nm, which would correspond to UV light, as UV light could damage the cells.

Additionally, the laser generator can be selected so that the wavelength of the generated light beam is close to 1000 nm, enabling using imaging techniques such as the two-photon illumination technique. Alternatively, the laser generator can be selected so that the wavelength of the generated light beam is on the near infrared (NIR) region.

According to the characteristics disclosed above, and by using the preferred wavelength, the photoactivators used in this invention are Eosin Y and lithium phenyl-2 4 6-trimethybenzoylphosphinate (LAP). Alternatively, other photoactivators that work in this particular wavelength, such as VA-086, could be used.

FIG. 2 shows a preferred second embodiment of the invention that additionally comprises at least one imaging system to track the photopolymerization process at real time. The imaging system makes possible to perform a visual inspection of the photopolymerization process at a real time, therefore allowing a simultaneous printing and tracking of the process. To ease the comprehensiveness of the figures, similar elements to the elements of the first embodiment are shown with similar reference numbers.

The imaging system is located in a position in which it can capture the output signal of the laser beam after said laser beam has irradiated the container 100 that contains the photopolymerizable polymer. Said imaging system comprises an objective lens 9a, 9b and an image capturing element, which is a CCD (charge-coupled device) camera 8a, 8b. FIG. 2 shows two of said imaging systems, being each of the imaging systems aligned with each of the laser beams 6a, 6b. Those CCD cameras are of a known type, and other cameras other than the described could be used.

Preferably, the objective lenses 9a, 9b have different characteristics of the objective lenses 5a, 5b. Unlike objective lenses 5a and 5b, the lenses 9a, 9b should offer, among other features, high numerical aperture, long focal length, low magnification and a large field of view. These objective lenses 9a, 9b allow taking “life” images at any certain moment of a further method of polymerization by using the device of the invention, which would help in a monitorization thereof. The characteristics of the objective lenses 9a, 9b could also be dependant of the characteristics of a camera attached to the device, in order to allow capturing images of the entire container 100, thus monitoring the entire sample.

In this particular embodiment, the polymers used in order to obtain polymer matrices with cells are preferably previously labelled with fluorescent probes. Said fluorescent probes can be vital dyes or protein markers, as well as other probes compatible with the wavelength of the light beam (the wavelength generated by the laser source), in order to be correctly visualized during the printing process. The presence of these fluorescent probes enables a better tracking of the printing process and the process of formation of the gels, polymers and cells in the containers.

FIG. 3A shows an optic module with a pattern generator. This optic module comprises a scanning mirror 7a, a scanning lens 2a, a tube lens 3a, a pattern generator 4a and at least an objective lens 5a. In an embodiment lacking a pattern generator, a bigger voxel would be irradiated by the light sheet beams at the point where those light sheets are crossed, therefore polimerizing a higher volume of the polymer. Depending on the characteristics of the laser beam, the whole polymer could be polymeried at once.

FIG. 3B shows a lateral scanning of a Gaussian type laser beam 6a, according to a known method of digital scanning light sheet microscopy (DSLM). This scanning system defines voxels in the light sheet, which are the theoretical lowest volume value which defines the minimum volume of light allowing polymer polymerization. When a voxel of the light sheet strikes on the polymer, a voxel 101 or 102 of the polymer is polymerized.

These light sheets 6a, 6b are crossed in a voxel of the polymer. The energy provided by the light sheets is enough to initiate polymerization and to achive the hardening of the photopolymer which can contain living cells. In this case, cells remain trapped in the hardened polymer in an effective manner. To obtain different results either exposition as well as the distance between the polymer, the laser generator and the angle of incidence of the light beams can be changed. These light sheets are coplanar, being both of them located in the same plane being the angle of incidence between both light sheets greater than 45°, in this case 90°. Alternatively, the orientation of the light sheets with respect to the container could be different as the one depicted in FIGS. 1 and 2, being the angle of incidence between both light sheets greater than 45°, more preferably 90°, for example being both light sheets rotated 90° around any axis. The present invention also discloses a particular embodiment in which the light beams 6a, 6b are not coplanar, shown in FIG. 4. Specifically, when the photopolymer contains living cells, the light sheet should have energy enough to initiate polymerization, but not affecting the living cells which should keep their viability and all their physical, chemical, and mechanical characteristics resembling to those cells present in within normal tissues.

In the present invention, the photopolymerizable polymer comprised in the container 100 contains living cells. When the light beams are crossed inside the container 100 and a voxel 101, 102 is polymerized, cells within the polymer are kept inside the polymerized voxel. In this manner, an illumination by light sheets coming from two different directions is used combined with high resolution digital photomasks, producing a local polymerization of cell-laden materials, so that tridimensional structures are created in a top-down lithographic process.

The photopolymerizable polymer is comprised in the container 100. Said container 100 is designed to also contain the living cells to be printed. The container 100 can be made of any material known to the skilled person, such as for example of fluorocarbon polymer. After printing, cell viability in the polymerized polymer is equal or greater than 99%.

In addition, the device may comprise data processing means, which comprise information of each voxel of the polymer, such as its index, position, and dose of energy required, having the pattern generator means for creating a tridimensional pattern in order to modulate the light beam to strike onto the polymer as accurate as possible. Furthermore, the device may comprise means for controlling the striking or irradiation time of the light beams.

In the above examples, the polymerizable polymer is an hydrogel. For photopolymerization, the hydrogel solution is placed in a container 100 which is a cuvette of fluorethylene polymer (FEP). Fluoroethylene is preferably because it has almost 100% transparency at all wavelengths, it has a wall thickness of ≤50 μm, and a refractive index n=1.34 close to the one for water, which is 1.33, in addition to being chemically inert and biocompatible. Preferably, containers have a square cross section and a minimun size of 1 mm×1 mm×1 mm, being most preferred containers of 10 mm×10 mm×10 mm. Alternatively, other materials and sizes can be used for the container, as well as the invention is not limited to fluourethylene.

The hydrogel used in the present invention can be any hydrogel known in the art. Preferably, said hydrogel is selected from a list comprising norbornene or thyol-functionalized polymers, including 4 arms norbornene PEG, gelatin methacrylate (GelMA) or poliethylenglycol diacrylate (PEGDA), or combination thereof. These two hydrogels are highly clear and their optical properties do not change with polymerization.

The photopolymerizable polymer may comprise a photoactivator. Said photoactivator is any photoactivator known in the art, preferably Eosin Y or lithium phenyl-2 4 6-trimethybenzoylphosphinate (LAP). Alternatively, other photoactivators such as VA-086 could be used.

FIG. 4 shows the incidence of two light sheets 6a, 6b, which are non-coplanar, inside the container 100. In the example shown, a first light sheet is in the XZ plane and a second light sheet is in the plane YZ.

As the light beams are in different planes, the result of their cross-link is a line instead of a plane. The polymerization of the photopolymerizable polymer at the crossing of said non-coplanar light sheets result in a slower polymerization than when the light sheets are coplanar, but still a higher speed than other configurations with only one light sheet.

The present invention also refers to a method for stereolithographic three dimensional printing. During this method, the container containing the photopolymerizable polymer can be rotated or moved linearly during the irradiating of the light sheets. By rotating and/or moving the container, this method allows performing perform a volumetric bioprinting or tomographic bioprinting based on tomographic back-projections, in which a 3D polymerized shape is generated by illuminating with tomographic back-projections generated by the modulated laser beams, which depending on the properties of the container and the polymer, results in a faster or more efficient method. This is also an alternative approach near “direct writing” to print a 3D shape out of the gel.

This schematic procedure for the volumetric bioprinting based on tomographic back-projections is a known procedure. One example of common procedure of this kind of volumetric bioprinting comprise creating an drawing of the 3D structure to be printed in a stereolithography format in any known computer-aided design (CAD) or modelling software, converting it to a stack of binary masks (“slicing”), calculating a sinogram or Radon transformation of each slice, and using sinograms to generate a spatial and intensity modulation of the light sheet illumination for each slice to further perform the gel polymerization within a container placed on a rotating platform so that at each angular step, the gel is illuminated by the light sheet patterned accordingly to the sinograms.

While the invention has been described and represented based on representative examples, it should be understood that said exemplary embodiments have no limiting effect on the present invention, so any of the variations that are included directly or by way of equivalence in the content of the appended claims should be considered to be included in the scope of the present invention.

1. A device for stereolithograpic three dimensional (3D) printing comprising:
a) a container adequate for containing a photopolymerizable polymer,
b) at least one laser generator emitting a light beam with a wavelength between 360 nm and 1000 nm,
c) modulation means for modulating said light beam into at least two light sheets which are matrices of light, and
d) means for irradiating said light sheets in the container containing said photopolymerizable polymer;
wherein said at least one laser generator is arranged so that said at least two light sheets are crossed inside said container, leading to polymerization of the photopolymerizable polymer at the crossing of said light sheets.

2. The device, according to claim 1, wherein said at least one laser generator is arranged so that said at least two light sheets are crossed inside said container containing said photopolymerizable polymer forming an angle greater than 45° between them.

3. The device, according to claim 1 further comprising means for rotating the container, means for linearly moving the container, and means for positioning the container to any spatial coordinate by both translation and rotation of the container.

4. The device, according to claim 1 further comprising means for moving the at least one laser generator.

5. The device, according to claim 1 further comprising at least two optic modules located downstream of said at least one laser generator, said optic modules comprising a scanning mirror and a scanning lens.

6. The device, according to claim 1 wherein said modulation means comprise at least one pattern generation system, said pattern generation system comprising a photomask.

7. The device, according to claim 1 further comprising an imaging system, said imaging system comprising an image capturing element and an objective lens.

8. The device, according to claim 1 further comprising means for controlling the time of emission of the light beams onto the container.

9. A method for stereolithographic three dimensional printing using a device according to claim 1, comprising the steps of:
a) providing a container adequate for containing a photopolymerizable polymer,
b) generating at least two light beams with a wavelength between 360 nm and 1000 nm by at least one laser generators,
c) modulating said light beams into light sheets,
d) irradiating said light sheets inside said container containing said photopolymerizable polymer, so that said light sheets are crossed inside said container, leading to polymerization of the photopolymerizable polymer occurs at the crossing of said light sheets.

10. The method, according to claim 9, further comprising an step of e) rotating and/or linearly moving the container containing the photopolymerizable polymer during the irradiating of the light sheets.

11. The method, according to claim 9, wherein the light beams are modulated into light sheets which are coplanar between them.

12. The method, according to claim 9, wherein said photopolymerizable polymer comprises a photoactivator.

13. The method, according to claim 9, wherein said photopolymerizable polymer is an hydrophilic polymer.

14. The method, according to claim 9, wherein said photopolymerizable polymer comprises living cells, said cells being selected from the list comprising mouse dermis cells (fibroblasts, lymphocytes, macrophages, endothelial cells, among other), or human cells such as dermal papilla, hair follicles, or sweat glands cells, and combinations thereof.

15. The method, according to claim 9, wherein the photopolymerizable polymer is a polymer labeled with fluorescent probes.
